(19) United States
(12) Patent Application Publication
(10) Pub. No.: US 2023/0124304 A1
(43) Pub. Date: Apr. 20, 2023

(54) CONTROLLED DELIVERY OF LOW-VAPOR-PRESSURE PRECURSOR INTO A CHAMBER

(71) Applicant: Applied Materials, Inc., Santa Clara, CA (US)

(72) Inventors: Kelvin Chan, San Ramon, CA (US); RUIYING HAO, San Jose, CA (US); WAYNE FRENCH, San Jose, CA (US); FARZAD HOUSHMAND, Mountain View, CA (US)

(21) Appl. No.: 17/903,892

(22) Filed: Sep. 6, 2022

Related U.S. Application Data
(60) Provisional application No. 63/255,846, filed on Oct. 14, 2021.

(51) Int. Cl. C23C 16/455; C23C 14/54; C23C 16/52

(52) U.S. Cl. CPC C23C 16/45512; C23C 14/54; C23C 16/52; C23C 16/45544

(57) ABSTRACT

Embodiments include a gas distribution assembly for a semiconductor processing chamber. In an embodiment, the gas distribution assembly comprises a flow ratio controller (FRC). In an embodiment, a first line from the FRC goes to an ampoule, and a second line from the FRC goes to a main line. In an embodiment, a third line from the ampoule goes to the main line. In an embodiment, a mass flow meter is coupled to the main line.

### CROSS-REFERENCE TO RELATED APPLICATIONS

This application claims the benefit of U.S. Provisional Application No. 63/255,846, filed on Oct. 14, 2021, the entire contents of which is hereby incorporated by reference herein.

### BACKGROUND

### 1) Field

Embodiments relate to the field of semiconductor manufacturing and, in particular, to delivering a low-vapor-pressure precursor into a chamber.

### 2) Description of Related Art

Vapor draw and bubbling are common methods of delivery of low-vapor-pressure precursors into a chamber (e.g., for physical vapor deposition (PVD) processes, chemical vapor deposition (CVD) processes, atomic layer deposition (ALD) processes, etc.). A carrier gas flows into a vessel (e.g., an ampoule) containing the precursor to help carry the precursor into the chamber. The shortcoming of vapor draw or bubbling is that the flow rate of the precursor is unmetered and uncontrolled. The lack of control of the amount of the precursor that is provided into the chamber can lead to variation within a single process and/or in variation between iterations of the process.

Direct liquid injection is a technique that can meter flow rates of liquid precursors. However, such techniques only work for liquid precursors and requires that the liquid be free of impurities that cause residue build-up along the delivery path. Attempts to meter and control flow rates with gas-phase concentration detection with absorption techniques have been developed, but they do not directly measure flow rates and require additional measurements. As such, they are not suitable for high volume manufacturing systems.

### SUMMARY

Embodiments include a gas distribution assembly for a semiconductor processing chamber. In an embodiment, the gas distribution assembly comprises a flow ratio controller (FRC). In an embodiment, a first line from the FRC goes to an ampoule, and a second line from the FRC goes to a main line. In an embodiment, a third line from the ampoule goes to the main line. In an embodiment, a mass flow meter is coupled to the main line.

In an embodiment, a method of flowing a precursor into a chamber is disclosed. In an embodiment, the method comprises flowing a carrier gas with a known flow rate into an input line, and splitting the carrier gas into a first portion and a second portion. In an embodiment, the method further comprises flowing the first portion through an ampoule that holds a precursor, and combining the first portion and a precursor gas with the second portion. In an embodiment, the method further comprises measuring a total gas flow after combining the first portion, the precursor gas, and the second portion.

In an embodiment, a processing tool for flowing a precursor into a chamber is provided. In an embodiment, the processing tool comprises a chamber, and a gas distribution assembly coupled to the chamber. In an embodiment, the gas distribution assembly comprises a mass flow controller (MFC), and a gas divider coupled to the MFC. In an embodiment, the gas divider splits a total gas flow from the MFC into a first portion and a second portion. In an embodiment, the gas distribution assembly further comprises a first gas line from the gas divider to an ampoule, and a second gas line from the gas divider to a main line. In an embodiment, a third gas line from the ampoule to the main line is provided. In an embodiment, the gas distribution assembly further comprises a mass flow meter between the main line and the chamber.

### BRIEF DESCRIPTION OF THE DRAWINGS

FIG. 1 is a schematic of a gas distribution assembly for delivering a measured amount of a low-vapor-pressure precursor into a chamber using a flow ratio controller (FRC), in accordance with an embodiment.

FIG. 2 is a schematic of a gas distribution assembly for delivering a measured amount of a low-vapor-pressure precursor into a chamber using a first mass flow controller and a second mass flow controller, in accordance with an embodiment.

FIG. 3A is a schematic of a gas distribution assembly for delivering a measured amount of a low-vapor-pressure precursor into a chamber using a first variable flow restrictor (VFR) and a second VFR, in accordance with an embodiment.

FIG. 3B is a schematic of a gas distribution assembly for delivering a measured amount of a low-vapor-pressure precursor into a chamber using a VFR and a fixed orifice, in accordance with an embodiment.

FIG. 3C is a schematic of a gas distribution assembly for delivering a measured amount of a low-vapor-pressure precursor into a chamber using a VFR and a fixed orifice, in accordance with an additional embodiment.

FIG. 4A is a schematic of a gas distribution assembly for delivering a measured amount of a low-vapor-pressure precursor into a chamber using a first MFC and a second MFC, in accordance with an embodiment.

FIG. 4B is a schematic of a gas distribution assembly for delivering a measured amount of a low-vapor-pressure precursor into a chamber using a first MFC and a second MFC, in accordance with an embodiment.

FIG. 5 is a flow diagram describing a process for measuring an amount of a low-vapor-pressure precursor that is delivered to a chamber using an FRC, in accordance with an embodiment.

FIG. 6 is a flow diagram describing a process for measuring an amount of a low-vapor-pressure precursor that is deliver to a chamber using a first mass flow controller and a second mass flow controller, in accordance with an embodiment.

FIG. 7 illustrates a block diagram of an exemplary computer system that may be used in conjunction with a gas distribution assembly, in accordance with an embodiment.

### DETAILED DESCRIPTION

Systems described herein include delivering a low-vapor-pressure precursor into a chamber. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, existing gas delivery processes are not capable of measuring an amount of a low-vapor-pressure precursor that is delivered into a processing chamber. As such, process uniformity (within a single process, or between iterations of a process) is difficult to control. Accordingly, embodiments disclosed herein include control logic and algorithms in order to quantify and control the flow rate of a low-vapor-pressure precursor, and associated hardware to implement such processes. In an embodiment, the methods and hardware are applicable to any low-vapor-pressure materials and processes. Additionally, the flow rate of the precursor at any point in time can be metered and/or controlled during each iteration of the process.

Particularly, embodiments disclosed herein include a process that involves splitting the flow of a carrier gas into a first portion and a second portion. The total flow of the carrier gas is a known quantity. For example, a mass flow controller can provide a desired amount of carrier gas into the system. The first portion may pass directly to a main gas line, and the second portion may be routed to an ampoule with a low-vapor-pressure solid or liquid precursor. The second portion carries the precursor into the main gas line to recombine with the first portion. At this point, the total carrier gas flow rate is known (i.e., the combination of the first portion and the second portion equals the value set by the mass flow controller), and a measurement of the total gas flow rate through the main gas line can be used to determine the contribution attributable to the precursor. As such, a quantitative value of the flow rate can be used to control the processing in the chamber. In an embodiment, the flow rate of the precursor may be controlled by modulating the percentage of the carrier gas that flows through the ampoule. That is, a larger precursor flow rate can be obtained by flowing more of the carrier gas through ampoule.

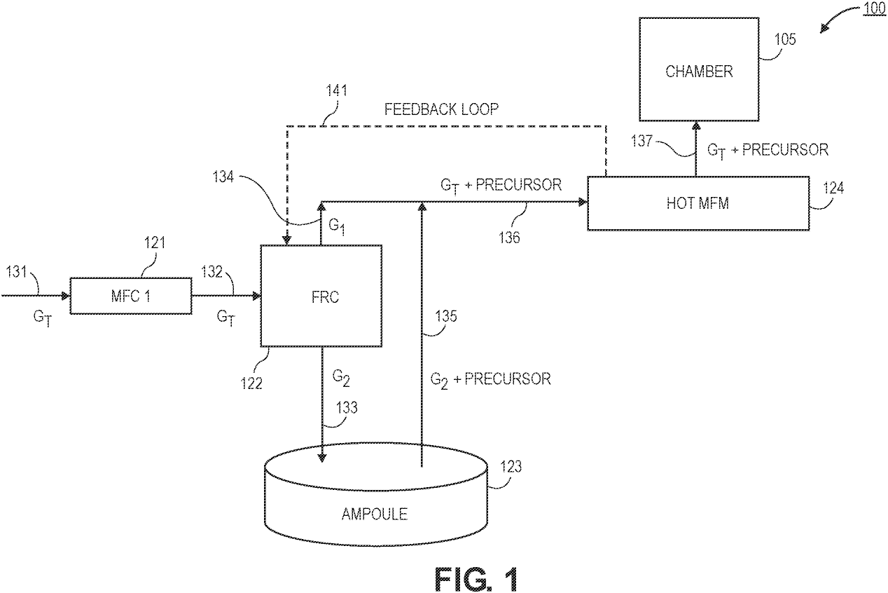

Referring now to FIG. 1, a schematic illustration of a processing tool 100 is shown, in accordance with an embodiment. In the illustrated embodiment, a portion of the gas delivery system that delivers a precursor to a chamber 105 is shown, in accordance with an embodiment. In an embodiment, the chamber 105 may be suitable for any process that includes the flow of a precursor gas. In a particular embodiment, the chamber 105 may be a physical vapor deposition (PVD) chamber, a chemical vapor deposition (CVD) chamber or an atomic layer deposition (ALD) chamber. However, it is to be appreciated that embodiments are not limited to such chamber types, and any semiconductor process that uses a precursor gas can utilize embodiments described herein.

In an embodiment, a gas input line 131 is coupled to a mass flow controller (MFC) 121. In an embodiment, the gas input line 131 is coupled to a gas source (not shown). In a particular embodiment, the gas source comprises an inert gas. For example, the gas source may comprise argon, though other inert gasses may also be used in some embodiments. In an embodiment, the MFC 121 meters the flow of the inert gas to a known total flow rate, indicated in FIG. 1 as G_{T}.

In an embodiment, an output line 132 of the MFC 121 is coupled to a flow ratio controller (FRC) 122. The FRC 122 is configured to separate the total flow G_{T} into a pair of inert gas flows, referred to as a first portion G₁ and a second portion G₂. The first portion G₁ passes along gas line 134 directly to a main gas line 136. The second portion G₂ passes along line 133 to an ampoule 133.

In an embodiment, the ampoule 133 comprises a precursor material. In an embodiment, the precursor material comprises a liquid or a solid. While not limited to any particular range, it is to be appreciated that embodiments disclosed herein are particularly beneficial for precursor materials that have a relatively low vapor pressure. That is, the amount of the precursor material that is in the gas phase may be relatively low. As such, a carrier gas is beneficial to aid in the transport of the limited amount of the gas phase of the precursor material. For example, the precursor material may include H₂O or the like.

In an embodiment, the second portion of the carrier gas G₂ and the precursor may be carried from the ampoule 123 to the main line 136 by gas line 135. At the main line 136, the first portion of the carrier gas G₁ and the second portion of the carrier gas G₂ recombine to form the total gas flow rate G_{T}. Additionally, the flow rate is augmented by the presence of the precursor.

In an embodiment, the main line 136 is fed to a mass flow meter (MFM) 124. The MFM 124 measures the total mass flow of the combined gas G_{T} and the precursor that passes through the gas line 137 into the chamber 105. Since the mass flow of the combined gas G_{T} is known (from the MFC 121), changes in the reading of the MFM 124 can be attributed to changes in the mass flow of the precursor material. In a particular embodiment, a quantitative measurement of the precursor mass flow rate may be obtained through the MFM 124. In other embodiments, the delta between the mass flow rate at the MFM 124 and the mass flow rate at the MFC 121 can be held steady by controlling the flow rate of the second portion G₂ or the temperature of the ampoule 123. In an embodiment, the MFM 124 may be temperature controlled in order prevent condensation of the precursor material. For example, the temperature of the MFM 124 may be maintained at a temperature up to approximately 150° C., or up to approximately 200° C.

In an embodiment, a feedback mechanism may also be included in the processing tool 100 in order to actively control the amount of precursor provided into the chamber 105. For example, a feedback loop 141 may connect from the MFM 124 to the FRC 122. In an embodiment, the reading from the MFM 124 is an output value that is provided to the FRC 122 in order to control a ratio of the second portion G₂ of the carrier gas to the first portion G₁ of the carrier gas. Increases to the ratio G₂/G₁ result in an increase in the precursor flow since more of the gas is fed to the ampoule 123. Decreases to the ratio G₂/G₁ result in a decrease in the precursor flow since less gas is fed to the ampoule 123. In an embodiment, the feedback loop 141 may include any type of control structure. For example, a PID controller may be included as part of the feedback loop 141, though it is to be appreciated that any type of controller may be used.

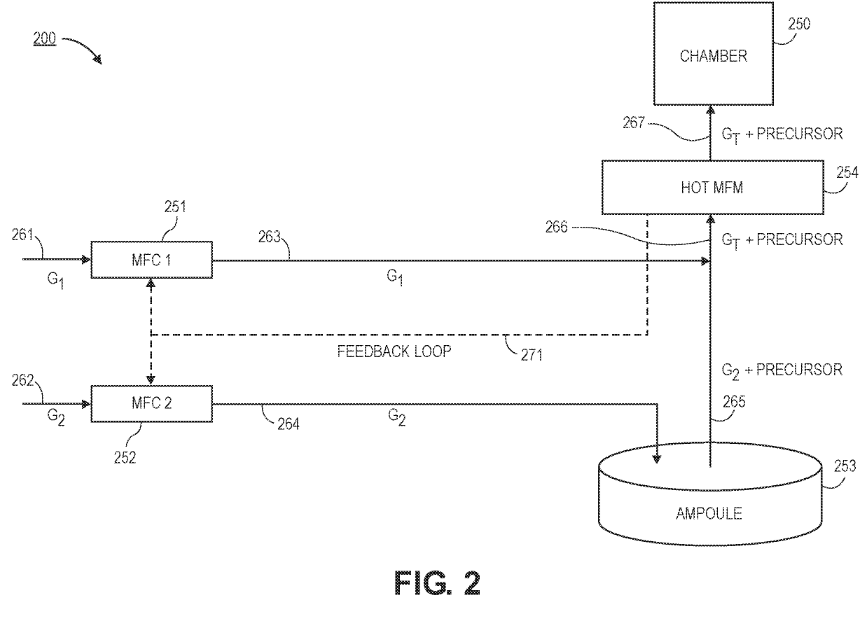

Referring now to FIG. 2, a schematic illustration of a processing tool 200 is shown, in accordance with an additional embodiment. In an embodiment, the processing tool 200 may be similar to the processing tool 100, with the exception of the control of the first portion G₁ and the second portion G₂. Instead of using a flow ratio controller, individual mass flow controllers 251 and 252 are used. In an embodiment, an increase in one of the mass flow controllers 251 or 252 may be matched by a decrease in the other of the mass flow controllers 251 or 252 in order to keep a total amount of carrier gas uniform.

In an embodiment, the processing tool 200 comprises a chamber 205. In an embodiment, the chamber 205 may be substantially similar to the chamber 105. For example, the chamber 205 may be suitable for any semiconductor processing operation that utilizes a precursor gas, such as a PVD chamber, a CVD chamber, or an ALD chamber.

In an embodiment, a first gas inlet line 261 is coupled to a first MFC 251, and a second gas inlet line 262 is coupled to a second MFC 252. The First MFC 251 provides a first gas G₁ to the system, and the second MFC 252 provides a second gas G₂ to the system. The first gas G₁ and the second gas G₂ may be an inert gas. In a particular embodiment, the first gas G₁ and the second gas G₂ comprise argon.

In an embodiment, the first gas G₁ is provided to a main gas line 266 by a gas line 263. The second gas G₂ is provided to the ampoule 253 by a gas line 264. In an embodiment, the ampoule 253 stores a precursor material. In an embodiment, the precursor material is a solid or a liquid. A vapor from the precursor material may be picked up by the carrier gas (i.e., the second gas G₂). In an embodiment, the precursor material may be considered a low-vapor-pressure material.

In an embodiment, the ampoule 253 is coupled to the main gas line 266 by gas line 265. As shown, the second gas G₂ and the precursor are propagated along the gas line 265 to the main gas line 266. In an embodiment, the first gas G₁, the second gas G₂, and the precursor combine together at the main gas line 266. The first gas G₁ and the second gas G₂ combine to be the total gas G_{T}. In an embodiment, the mass flow rate of the total gas G_{T} may be substantially equal to the combination of the mass flow rates dictated by the first MFC 251 and the second MFC 252, which are known values.

The main gas line 266 may feed into the MFM 254. The MFM 254 measures the mass flow rate of the combination of the total gas G_{T} and the precursor that passes through the gas line 267 into the chamber 205. Since the mass flow rate of the total gas G_{T} is known, the mass flow rate of the precursor can be deduced by subtraction. As such, a quantitative measurement of the precursor flow rate may be provided in accordance with embodiments described herein.

In an embodiment, the processing tool 200 may further comprise a feedback loop 271. The feedback loop 271 may provide a control effort to the MFCs 251 and 252 in order to control the quantity of the precursor that is delivered to the chamber 205. In an embodiment, the feedback loop 271 may include any type of control structure. For example, a PID controller may be included as part of the feedback loop 271, though it is to be appreciated that any type of controller may be used. In an embodiment, an increase in the flow rate of one of the MFCs 251 or 252 may be matched with a substantially equal decrease in the flow rate of the other one of the MFCs 251 or 252. In this way, the total gas G_{T} value may remain substantially uniform while the flow rate of the precursor can be modulated. For example, an increase in the flow rate of the second MFC 252 may result in an increase in the flow rate of the precursor into the chamber.

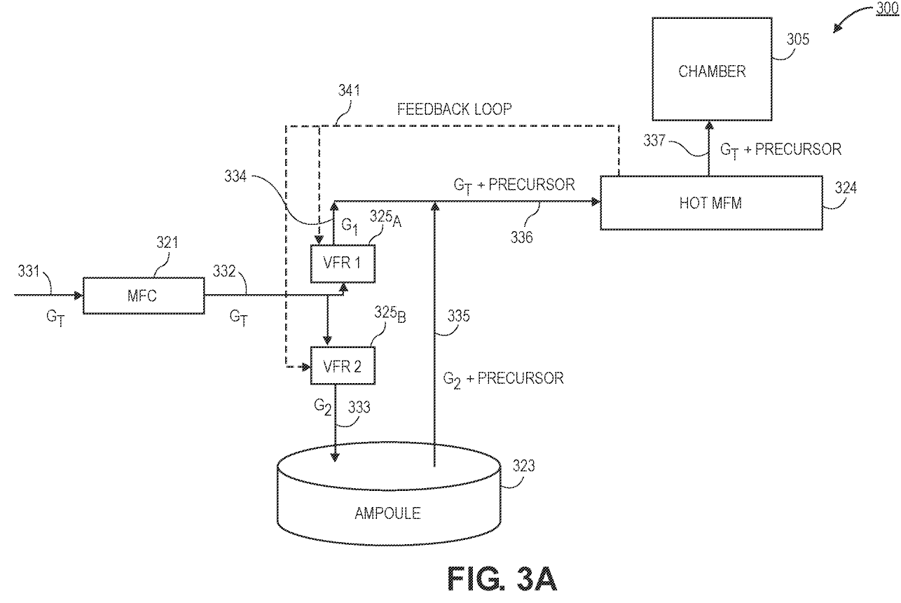

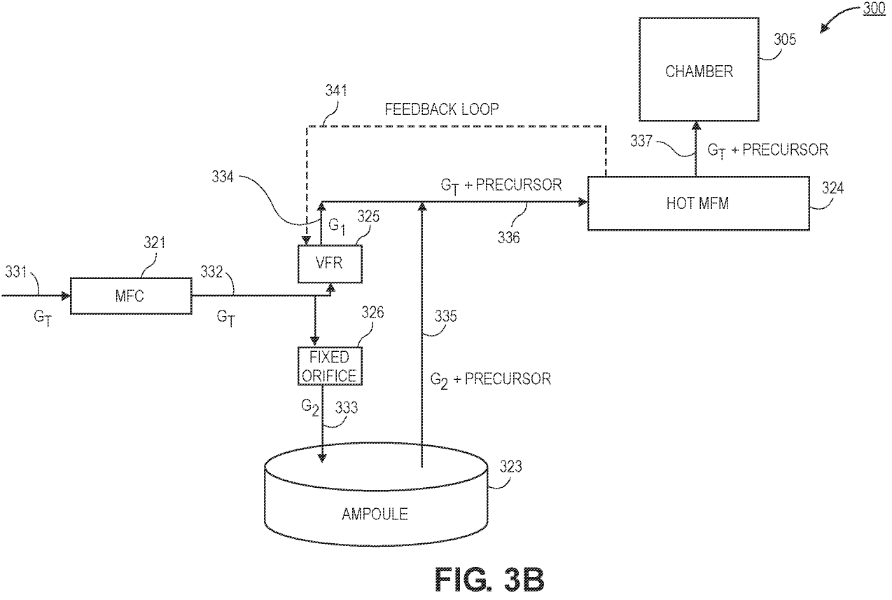

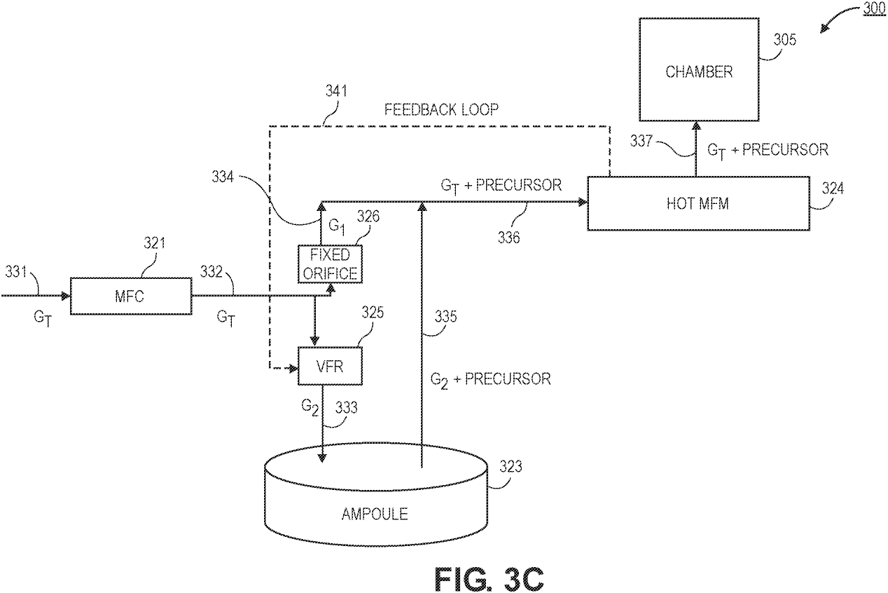

Referring now to FIG. 3A, a schematic illustration of a processing tool 300 is shown, in accordance with an additional embodiment. In an embodiment, the processing tool 300 may be similar to the processing tool 100, with the exception of the control of the first portion G₁ and the second portion G₂. Instead of using a flow ratio controller, variable flow restrictors (VFRs) 325_{A} and 325_{B} are used to split the first portion G₁ and the second portion G₂.

In an embodiment, the processing tool 300 may comprise a gas input line 331 that provides a source of a carrier gas G. In an embodiment, a MFC 321 controls the flow of the carrier gas G_{T} into the gas line 332. In an embodiment, a first branch of the gas line 332 ends at VFR1 325_{A}, and a second branch of the gas line 332 ends at VFR2 325_{B}. An output line 334 connects the VFR1 325_{A} to a main line 336 to provide a first portion of the carrier gas G₁ to the main line. In an embodiment, an output line 333 couples the VFR2 325_{B} to an ampoule 323 in order to flow the second portion of the carrier gas G₂ to the ampoule 323. In an embodiment, the ampoule 323 may comprise a solid or liquid precursor source. The flow of the carrier gas through the ampoule 323 picks up the precursor and delivers the second portion of the carrier gas G₂ and the precursor to the main line 336 via a gas line 335.

At the main line 336, the first portion of the carrier gas G₁ and the second portion of the carrier gas G₂ recombine to form the total carrier gas G_{T}. Additionally, the precursor is included along the main line 336. The main line 336 feeds into the MFM 324, which provides a measurement of the total gas that flows through line 337 to the chamber 305. Since the total carrier gas G_{T} is a known quantity from the MFC 321, the MFM 324 can be used to determine the quantity of the precursor provided to the chamber 305.

In an embodiment, a feedback loop 341 from the MFM 324 may be provided between the MFM 324 and the VFRs 325_{A} and 325_{B}. The feedback loop 341 may comprise a controller that controls the flow through the VFRs 325_{A} and 325_{B} in order to modulate the flow of the precursor into the chamber. For example, increasing the flow of the second portion of the carrier gas G₂ results in more of the precursor being flown into the chamber. In an embodiment, the feedback loop 341 may include any type of control structure. For example, a PID controller may be included as part of the feedback loop 341, though it is to be appreciated that any type of controller may be used.

Referring now to FIG. 3B, a schematic illustration of a processing tool 300 is shown, in accordance with an additional embodiment. In an embodiment, the processing tool 300 may be similar to the processing tool 300 in FIG. 3A, with the exception of the control of the first portion G₁ and the second portion G₂. Instead of using a pair of VFRs 325_{A} and 325_{B} to split the first portion G₁ and the second portion G₂, a VFR 325 controls the flow of the first portion G₁ and a fixed orifice 326 controls the flow of the second portion G₂. In some embodiments, the feedback loop 341 may couple the MFM 324 to the VFR 325 to control the flow of the first portion G₁.

Referring now to FIG. 3C, a schematic illustration of a processing tool 300 is shown, in accordance with an additional embodiment. In an embodiment, the processing tool 300 may be similar to the processing tool 300 in FIG. 3B, with the exception of the positioning of the VFR 325 and the fixed orifice 326. In the embodiment shown in FIG. 3C, the VFR 325 controls the flow of the second portion of the carrier gas G₂ and the fixed orifice 326 controls the flow of the first portion of the carrier gas G₁.

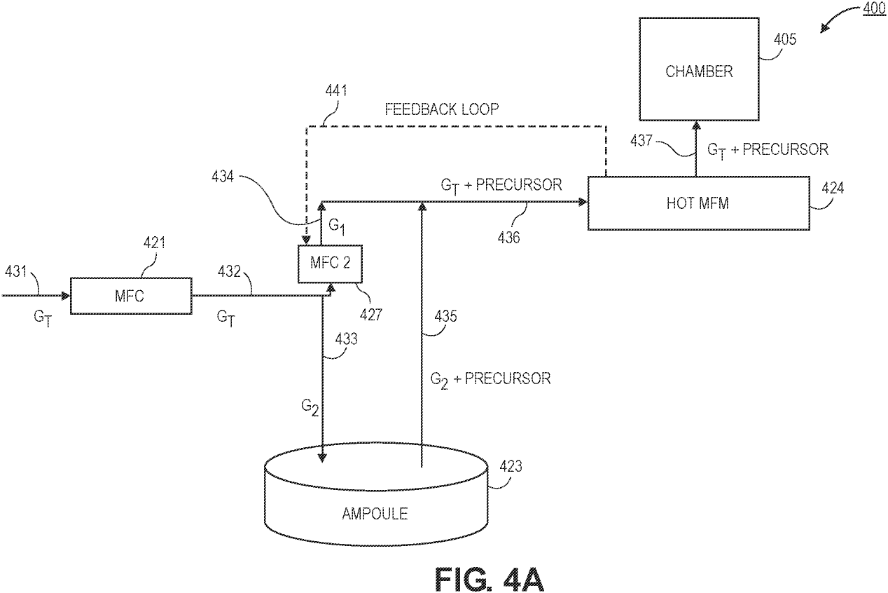

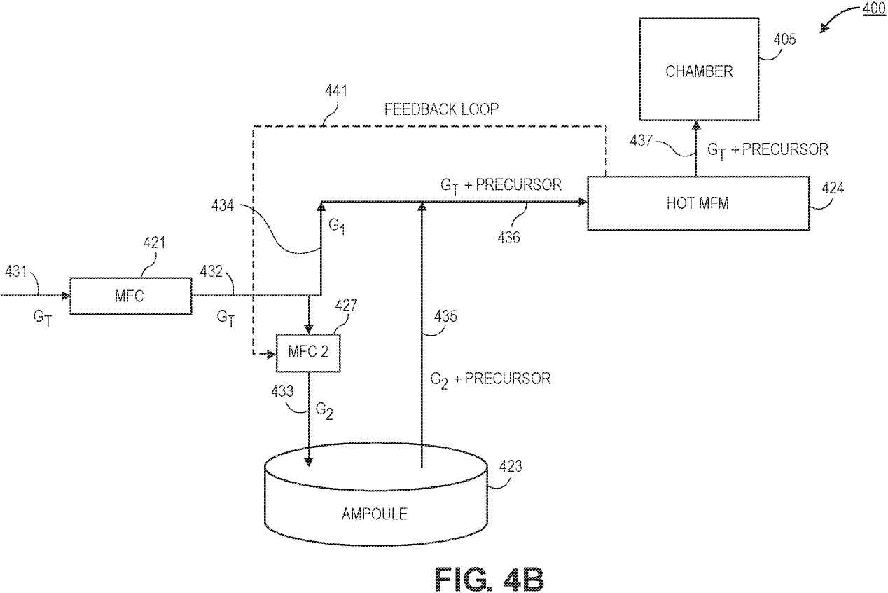

Referring now to FIG. 4A, a schematic illustration of a processing tool 400 is shown, in accordance with an embodiment. In an embodiment, a gas input line 431 provides a carrier gas G to a first MFC 421. The MFC1 controls the total flow of carrier gas G_{T} into the system along line 432. In an embodiment a first branch of the gas line 432 ends at second MFC 427. The second MFC 427 controls the flow of a first portion of the carrier gas G₁ along line 434 to the main line 436. In an embodiment, the remaining portion of the gas (i.e., the second portion of the carrier gas G₂) is provided to the ampoule 423 along gas line 433. The second portion of the carrier gas G₂ picks up the precursor in the ampoule 423, and the second portion of the carrier gas G₂ and the precursor are provided to the main line 436 along gas line 435.

At the main line 436, the first portion of the carrier gas G₁ and the second portion of the carrier gas G₂ recombine to provide a total carrier gas G_{T} and the precursor. The main line 436 feeds into the MFM 424. The MFM 424 measures the amount of gas flowing through the line 437 to the chamber 405. Since the total carrier gas G_{T} is known, the MFM 424 is able to calculate the amount of precursor that is flown into the chamber 405. In an embodiment, a feedback loop 441 couples the MFM 424 to the second MFC 427 in order to be able to control the flow through the MFM 424 and the amount of precursor provided to the main line 436. In an embodiment, the feedback loop 441 may include any type of control structure. For example, a PID controller may be included as part of the feedback loop 441, though it is to be appreciated that any type of controller may be used. Decreasing the flow of the first portion of the carrier gas G₁ results in an increase in the flow of the second portion of the carrier gas G₂ and more precursor is carried to the main line 436.

Referring now to FIG. 4B, a schematic illustration of a processing tool 400 is shown, in accordance with an additional embodiment. The processing tool 400 in FIG. 4B may be substantially similar to the processing tool 400 in FIG. 4A, with the exception of the positioning of the second MFC 427. Instead of using the MFC 427 to control the first portion of the carrier gas G₁, the MFC 427 is used to control the second portion of the carrier gas G₂. As such, the MFC 427 can be used to directly control the amount of precursor that is flown into the main line 436.

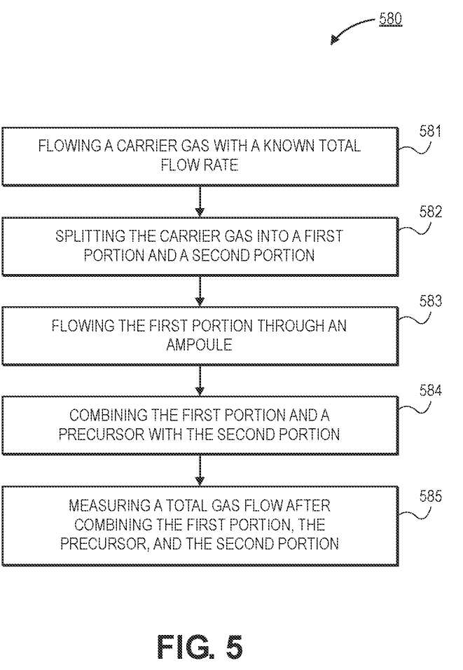

Referring now to FIG. 5, a flow diagram describing a process 580 for controlling the flow of a precursor into a chamber is shown, in accordance with an embodiment. In an embodiment, the precursor may be a material that has a low vapor pressure. The precursor is carried into the chamber with a carrier gas, such as argon. In an embodiment, the amount of the precursor that is flown into the chamber can be quantitatively measured to provide repeatable processing within the chamber.

In an embodiment, the process 580 may begin with operation 581, which comprises flowing a carrier gas with a known total flow rate. For example, the carrier gas may be flown through an MFC. The MFC provides a known quantity of the carrier gas that is flown into the system.

In an embodiment, the process 580 may continue with operation 582, which comprises splitting the carrier gas into a first portion and a second portion. For example, the carrier gas may be split by an FRC or the like. In an embodiment, the first portion of the carrier gas is routed to an ampoule. For example, operation 583 comprises flowing the first portion through an ampoule. The first portion of the carrier gas may pick up a precursor vapor that is in the ampoule. For example, the precursor may comprise a solid or a liquid precursor that puts out a precursor vapor. In an embodiment, the second portion of the carrier gas is routed to a main gas line.

In an embodiment, the process 580 may continue with operation 584, which comprises combining the first portion of the carrier gas and the precursor with the second portion of the carrier gas in the main gas line. Recombining the first portion of the carrier gas and the second portion of the carrier gas results in the total carrier gas flow in the main gas line being equal to the total gas flow provided by the MFC.

In an embodiment, the process 580 may continue with operation 585, which comprises measuring a total gas flow after combining the first portion of the carrier gas, the precursor, and the second portion of the carrier gas. In an embodiment, the total gas flow may be measured by a MFM, or the like. In order to calculate the amount of the precursor that is present, the sum of the first portion of the carrier gas and the second portion of the carrier gas (which is a known quantity) is subtracted from the total gas flow.

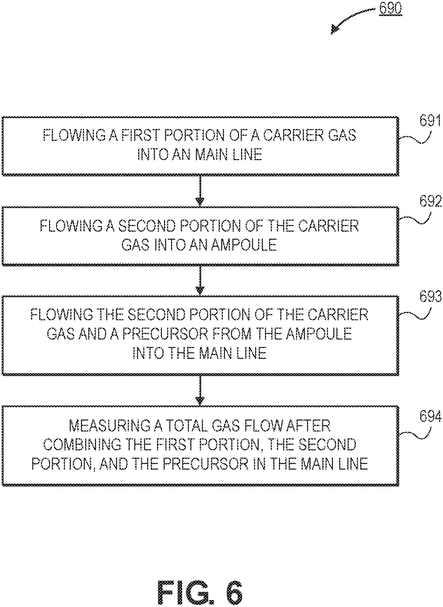

Referring now to FIG. 6, a flow diagram of a process 690 for controlling the flow of a precursor into a chamber is shown, in accordance with an embodiment. In an embodiment, the precursor may be a low vapor pressure material. The precursor may be stored in an ampoule, and a carrier gas may bring the precursor vapor into the chamber. In an embodiment, the process 690 may begin with operation 691, which comprises flowing a first portion of a carrier gas into a main gas line. In an embodiment, the flow rate of the first portion of the carrier gas may be controlled with a first MFC.

In an embodiment, the process 690 may continue with operation 692, which comprises flowing a second portion of the carrier gas into the ampoule. In an embodiment, the flow rate of the second portion of the carrier gas may be controlled with a second MFC. Since both the first portion of the carrier gas and the second portion of the carrier gas are metered with MFCs, the total gas flow into the system is a known quantity.

In an embodiment, the process 690 may continue with operation 693, which comprises flowing the second portion of the carrier gas and the precursor from the ampoule into the main gas line. At this point, the first portion of the carrier gas, the second portion of the carrier gas, and the precursor are combined into a single gas line.

In an embodiment, the process 690 may continue with operation 694, which comprises measuring a total gas flow after combining the first portion of the carrier gas, the second portion of the carrier gas, and the precursor in the main gas line. In an embodiment, the total gas flow rate may be measured by a MFM or the like. In an embodiment, the flow rates of the first portion of the carrier gas and the second portion of the carrier gas may be subtracted from the total gas flow rate in order to provide a quantitative value of the flow rate of the precursor into the chamber.

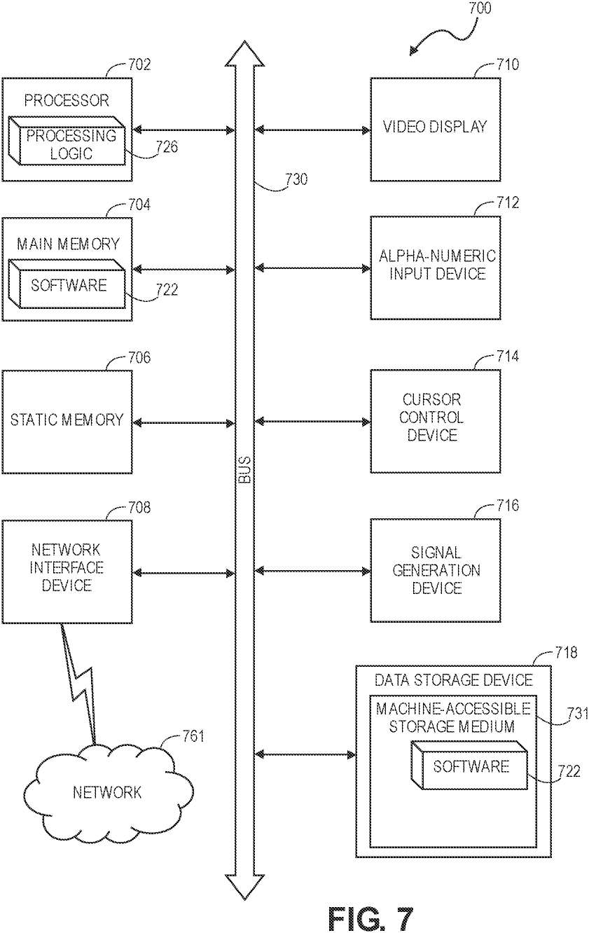

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 732 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 720 via the system network interface device 708. In an embodiment, the network interface device 708 may operate using RF coupling, optical coupling, acoustic coupling, or inductive coupling.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A gas distribution assembly, comprising:
a flow ratio controller (FRC);
a first line from the FRC to an ampoule;
a second line from the FRC to a main line;
a third line from the ampoule to the main line; and
a mass flow meter coupled to the main line.

2. The gas distribution assembly of claim 1, wherein the ampoule comprises a low vapor pressure precursor.

3. The gas distribution assembly of claim 2, wherein the precursor is a solid.

4. The gas distribution assembly of claim 2, wherein the precursor is a liquid.

5. The gas distribution assembly of claim 1, further comprising:
a feedback line from the mass flow meter to the FRC.

6. The gas distribution assembly of claim 5, wherein the feedback line provides a control signal to the FRC that changes a ratio of the gas flown into the first line and the gas flown into the second line.

7. The gas distribution assembly of claim 1, wherein the mass flow meter is temperature controlled.

8. The gas distribution assembly of claim 7, wherein the mass flow meter is heated to a temperature up to approximately 150° C.

9. The gas distribution assembly of claim 1, further comprising:
a mass flow controller (MFC) to control a flow of gas into the FRC.

10. The gas distribution assembly of claim 1, wherein an outlet of the mass flow meter is coupled to a chamber.

11. The gas distribution assembly of claim 10, wherein the chamber is suitable for physical vapor deposition (PVD), chemical vapor deposition (CVD) or atomic layer deposition (ALD).

12. A method of flowing a precursor into a chamber, comprising:
flowing a carrier gas with a known flow rate into an input line;
splitting the carrier gas into a first portion and a second portion;
flowing the first portion through an ampoule that holds a precursor;
combining the first portion and a precursor gas with the second portion; and
measuring a total gas flow after combining the first portion, the precursor gas, and the second portion.

13. The method of claim 12, wherein the carrier gas comprises argon.

14. The method of claim 12, wherein the precursor is a solid precursor or a liquid precursor.

15. The method of claim 12, wherein the first portion carries the precursor gas out of the ampoule.

16. The method of claim 15, wherein a flow rate of the precursor gas is determined by subtracting the known flow rate from the total gas flow.

17. The method of claim 12, wherein the chamber is configured to provide physical vapor deposition (PVD) processes, chemical vapor deposition (CVD) processes or atomic layer deposition (ALD) processes.

18. A processing tool, comprising:
a chamber; and
a gas distribution assembly coupled to the chamber, wherein the gas distribution assembly comprises:
a mass flow controller (MFC);
a gas divider coupled to the MFC, wherein the gas divider splits a total gas flow from the MFC into a first portion and a second portion;
a first gas line from the gas divider to an ampoule;
a second gas line from the gas divider to a main line;
a third gas line from the ampoule to the main line; and
a mass flow meter between the main line and the chamber.

19. The processing tool of claim 18, wherein the gas divider comprises a variable flow restrictor and a fixed orifice.

20. The processing tool of claim 18, wherein the gas divider comprises a second MFC.
